(19) United States
(12) Patent Application Publication
(10) Pub. No.: US 2010/0043873 A1
(43) Pub. Date: Feb. 25, 2010

(54) SEMICONDUCTING DEVICES AND METHODS OF MAKING THE SAME

(76) Inventors: Yong Hyup Kim, Seoul (KR); Hyeong Uk Im, Seoul (KR)

Correspondence Address: FOLEY & LARDNER LLP, 150 EAST GILMAN STREET, P.O. BOX 1497, MADISON, WI, 53701-1497, US

(21) Appl. No.: 12/197,561

(22) Filed: Aug. 25, 2008

(51) Int. Cl. H01L 31/0336; H01L 29/225; H01L 21/34; H01L 31/18

(52) U.S. Cl. 136/255; 257/43; 438/104; 438/94; 257/E29.097; 257/E31.005; 257/E21.46

(57) ABSTRACT

A semiconducting device includes a p-type semiconducting layer; a plurality of nanostructures extending from the p-type semiconducting layer; and a n-type semiconducting layer, wherein the n-type semiconducting layer coats the p-type semiconducting layer and the plurality of nanostructures. A photovoltaic cell includes a p-type layer; a plurality of nanowires protruding from the p-type layer; and a n-type layer deposited on the p-type layer and the plurality of nanowires forming a heterojunction.

### BACKGROUND

Semiconducting devices are electronic components that utilize the electronic properties of semiconductor materials, e.g., silicon, germanium, and gallium arsenide. The intrinsic electrical properties of semiconducting devices are often modified by introducing impurities by a process known as doping. Upon the addition of a sufficiently large proportion of dopants, semiconductors will conduct electricity nearly as well as metals. Depending on the type of dopants, a doped region of a semiconductor can have more electrons or “holes” and is typically called a n-type or p-type semiconductor, respectively. An electric field is established across the junction between the n-type semiconductor and p-type semiconductor, i.e., the p-n junction, creating a diode that promotes current to flow in only one direction across the junction, providing the basis for many semiconducting devices. Other commonly known semiconductor devices include photodiodes, light emitting diodes, transistors, magnetic field sensors, etc.

### SUMMARY

Embodiments of semiconducting devices, photovoltaic cells, and methods for making such devices are disclosed herein. In accordance with one embodiment by way of non-limiting example, a semiconducting device includes a p-type semiconducting layer, a plurality of nanostructures extending from the p-type semiconducting layer, and a n-type semiconducting layer, where the n-type semiconducting layer coats the p-type semiconducting layer and the plurality of nanostructures.

In another embodiment, a photovoltaic cell includes a p-type layer, a plurality of nanowires protruding from the p-type layer, and a n-type layer deposited on the p-type layer and the plurality of nanowires forming a heterojunction.

In another embodiment, a method for making a semiconducting device includes forming a plurality of nanostructures extending from a p-type semiconducting layer, and forming a n-type semiconducting layer on the p-type semiconducting layer and on the plurality of nanostructures.

In another embodiment, a method for making a photovoltaic cell includes forming a plurality of nanowires on a p-type layer, and coating the plurality of nanowires and the p-type layer with a n-type layer, resulting in a heterojunction.

The foregoing is a summary and thus contains, by necessity, simplifications, generalization, and omissions of detail; consequently, those skilled in the art will appreciate that the summary is illustrative only and is not intended to be in any way limiting. Other aspects, features, and advantages of the devices and/or processes and/or other subject matter described herein will become apparent in the teachings set forth herein. The summary is provided to introduce a selection of concepts in a simplified form that are further described below in the Detailed Description. This summary is not intended to identify key features or essential features of the claimed subject matter, nor is it intended to be used as an aid in determining the scope of the claimed subject matter.

### BRIEF DESCRIPTION OF THE DRAWINGS

The foregoing and other features of the present disclosure will become more fully apparent from the following description and appended claims, taken in conjunction with the accompanying drawings. Understanding that these drawings depict only several embodiments in accordance with the disclosure and are, therefore, not to be considered limiting of its scope, the disclosure will be described with additional specificity and detail through use of the accompanying drawings.

FIG. 1 shows an illustrative embodiment of a semiconducting device.

FIG. 2 shows an illustrative embodiment of a photovoltaic cell.

FIGS. 3A-D are schematic diagrams showing an illustrative embodiment of a method of making a semiconducting device.

FIGS. 4A-D are schematic diagrams of illustrative embodiments of a p-type semiconducting layer with a plurality of copper oxide nanostructures extending therefrom.

FIG. 5 shows an illustrative embodiment of a semiconducting device having a plurality of semiconducting layers.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented here. It will be readily understood that the components of the present disclosure may be arranged and designed in a wide variety of different configurations. In view of the present disclosure, those of ordinary skill will appreciate that the functions performed in the methods may be implemented in differing order, and that the outlined steps are provided only as examples, and some of the steps may be optional, combined into fewer steps, or expanded to include additional steps without detracting from the essence of the present disclosure.

As used in the specification and the claims, a “nanostructure” refers to a structure of an intermediate size between molecular and microscopic structures, such as a nanowire. In the present disclosure, a “nanostructure” also encompasses other similar-shaped structures including, but not limited to, nanorods, nanofibers, nanopillars, nanoneedles, nanocones, and nanothorns.

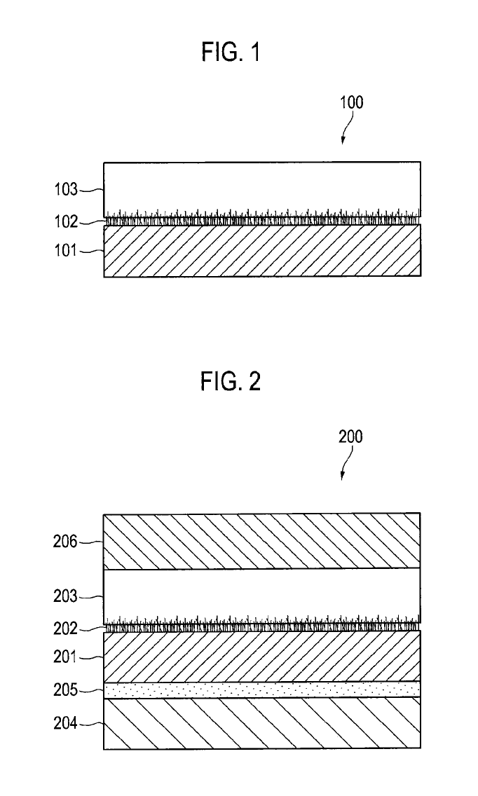

In one aspect, the present disclosure provides for semiconducting devices. Referring to FIG. 1, an illustrative embodiment of a semiconducting device 100 is shown. In certain embodiments, the semiconducting device 100 includes a p-type semiconducting layer 101, a plurality of nanostructures 102, and a n-type semiconducting layer 103. The n-type semiconducting layer 103 coats the p-type semiconducting layer 101 and the plurality of nanostructures 102. In one embodiment by way of non-limiting example, the semiconducting device 100 may be a photocatalyst.

The p-type semiconducting layer 101 may include a metal oxide, such as but not limited to copper oxide, titanium dioxide, and tungsten oxide. In some embodiments, the p-type semiconducting layer 101 may include a copper oxide, such as but not limited to cuprous oxide, cupric oxide, and a combination thereof.

The plurality of nanostructures 102 extend from the p-type semiconducting layer 101, as illustrated in FIG. 1, and are made of a p-type semiconductor material such as metal oxides, including but not limited to copper oxide, titanium dioxide, and tungsten oxide. The plurality of nanostructures 102, e.g., nanowires, may be arranged randomly or in an orderly direction. In some embodiments, the plurality of nanostructures 102 may include carbon nanotubes.

The n-type semiconducting layer 103 may include a metal oxide. In some embodiments, the n-type semiconducting layer 103 may include a metal oxide, such as but not limited to titanium dioxide, tin dioxide, and zinc oxide.

In another embodiment, the n-type semiconducting layer 103 may include a transparent conductive film, such as but not limited to, transparent conductive oxides, fluorine-doped tin oxides (SnO₂:F), doped zinc oxides (e.g., ZnO:Al), and indium tin oxides.

To enhance the efficiency of the semiconducting device, the p-type and/or n-type semiconducting layers may be doped by diffusion with various dopants, such as B, Al, Ga, Ma, Be, W, Mo, Zn, Al, Sr, Y, Gd, Ni, N, P, As, Sb, and the like, without disturbing the chemical, morphological, and/or physical properties of the device. In other embodiments, the p-type and/or n-type semiconducting layers may be doped with dopants by ion implantation.

In some embodiments, the semiconducting device 100 may further include a substrate on which the p-type semiconducting layer 101 is formed. Suitable substrates include, but are not limited to, metal, alloy, glass, ceramic, silicon, plastic, sapphire, diamond, gallium arsenide, quartz, germanium, and the like.

Referring back to FIG. 1, the n-type semiconducting layer 103 coats the p-type semiconducting layer 101 and the plurality of nanostructures 102 extending therefrom. Thus, the p-n heterojunction of the semiconducting device 100 is formed on the base surface of the p-type semiconducting layer 101 and also around the plurality of nanostructures 102 extending from the p-type semiconducting layer 101. In contrast, the p-n heterojunction of a conventional semiconducting device (i.e., without the above-described nanostructures) is formed only between the p- and n-type semiconducting layers. Accordingly, the total area of the p-n heterojunction of the semiconducting device 100 can be increased.

Further, the numerous nanostructures 102 extending from the p-type semiconducting layer 101 may provide more paths along which light rays travel near the p-n heterojunction, where the incident light randomly changes its direction when hitting the nanostructures 102. As a result, the semiconducting device 100 exhibits at least a greater efficiency.

Referring to FIG. 2, an illustrative embodiment of a photovoltaic cell 200 is shown. The photovoltaic cell 200 optionally includes a p-type layer 201, a plurality of nanowires 202, a n-type layer 203, a substrate 204, a counter electrode 205, and an electrode 206. The plurality of nanowires 202 protrude from the p-type layer 201, as illustrated in FIG. 2. The n-type layer 203 is deposited on the p-type layer 201 and the plurality of nanowires 202, forming a p-n heterojunction.

Descriptions regarding the components illustrated in FIG. 2, for example, the p-type layer 201, the plurality of nanowires 202, and the n-type layer 203, which are similar to the p-type semiconducting layer 101, the plurality of nanostructures 102, and the n-type semiconducting layer 103 already described and illustrated in FIG. 1, are not necessarily repeated herein.

In some embodiments, where the substrate 204 is either plastic or silicon, the counter electrode 205 may be a metal, such as aluminum or silver. In other embodiments, where the substrate 204 is glass and the counter electrode 205 is a transparent conductive film, the electrode 206 deposited on the n-type layer may be a metal.

The photovoltaic cell may include an anti-reflection layer (not shown in FIG. 2), for increasing the amount of light received by the photovoltaic cell. The anti-reflection layer may include, by way of non-limiting example, ZnS, Sb₂O₃, SiO₂ or SiO.

Because the p-n heterojunction of the photovoltaic cell 200 is formed not only on the base surface of the p-type layer 201 but also around the plurality of nanowires 202 protruding from the p-type layer 201, the total area of the p-n heterojunction of the photovoltaic cell 200 is increased.

In addition, the plurality of nanowires 202 may provide more paths along which light rays travel near the p-n heterojunction, since the plurality of nanowires 202 generate a geometrically complex space for the light to travel. Accordingly, the photovoltaic cell 200 should absorb an increased amount of photon energy, enhancing the photon-to-current conversion efficiency of the photovoltaic cell 200.

Depending on the specific design requirements and/or what the semiconducting device is being used for, the shapes, the arrangements of the plurality of nanostructures on the p-type semiconducting layers, and other additional components may differ. For example, when the above illustrated semiconducting device is to be used for a sensor, the plurality of nanostructures may be configured to extend in a direction that is generally perpendicular to the surface of the p-type semiconducting layer to increase the sensitivity of the manufactured sensor.

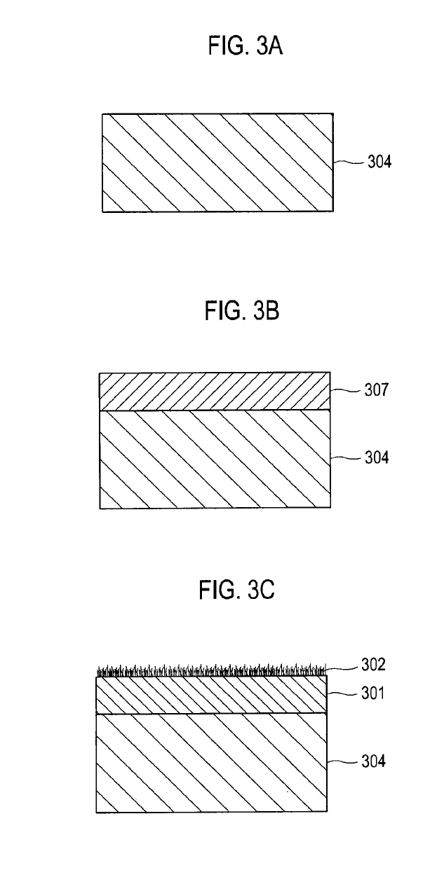

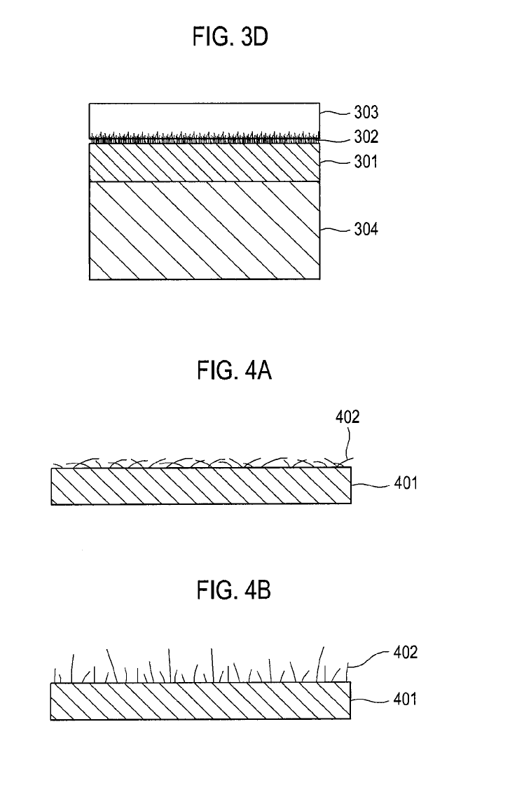

FIGS. 3A-D show an illustrative embodiment of a method of making a semiconducting device. Referring to FIG. 3A, the method for making a semiconducting device optionally includes providing a substrate 304. Next, as illustrated in FIG. 3B, a metal film 307 may be deposited on the substrate 304. The metal film 307 may include a metal, such as but not limited to copper, titanium, and tungsten. The metal film 307 may have a thickness of, but is not limited to, from about 1000 Å to 1 mm. In some embodiments, the thickness of the metal film 307 may range from about 3000 Å to about 1 mm, from about 5000 Å to about 1 mm, from about 1 μm to about 1 mm, from about 10 μm to about 1 mm, from about 50 μm to about 1 mm, from about 100 μm to about 1 mm, from about 500 μm to about 1 mm, from about 1000 Å to about 3000 Å, from about 1000 Å to about 5000 Å, from about 1000 Å to about 1 μm, from about 1000 Å to about 10 μm, from about 1000 Å to about 50 μm, from about 1000 Å to about 100 μm, from about 1000 Å to about 500 μm, from about 3000 Å to 5000 Å, from about 5000 Å to about 1 μm, from about 1 μm to about 10 μm, from about 10 μm to about 50 μm, from about 50 μm to about 100 μm, or from about 100 μm to about 500 μm. In other embodiments, the thickness of the metal film 307 maybe about 1000 Å, about 2500 Å, about 3000 Å, about 5000 Å, about 1 μm, about 10 μm, about 50 μm, about 100 μm, about 500 μm, or about 1 mm. The thickness of the metal film 307 is selected such that the overall transparency of the manufactured device is not substantially reduced. For example, when the device is a photovoltaic cell, a photocatalyst, or the like, the thickness of the metal film 307 may be selected such that the device has a visible light transmittance of about 60% or more.

As illustrated in FIG. 3C, a plurality of nanostructures 302 extending from a p-type semiconducting layer 301 may be formed using the metal film 307 as a seed layer. In some embodiments, the conditions effective for forming the plurality of nanostructures 302 extending from the p-type semiconducting layer 301 may be an oxidation treatment of the metal film 307 by an alkaline solution. For example, the metal film 307, i.e., the seed layer, may be immersed in an alkaline solution, where it is oxidized into a p-type metal oxide layer having a plurality of nanostructures extending therefrom. The immersing of the metal film 307 in the alkaline solution may be carried out at a temperature of, by way of non-limiting example, from about 50° C. to about 200° C. In some embodiments, the temperature for the alkaline solution treatment may range from about 60° C. to about 200° C., from about 70° C. to about 200° C., from about 90° C. to about 200° C., from about 120° C. to about 200° C., from about 150° C. to about 200° C., from about 180° C. to about 200° C., 50° C. to about 180° C., from about 50° C. to about 150° C., from about 50° C. to about 120° C., from about 50° C. to about 90° C., from about 50° C. to about 70° C., from about 50° C. to about 60° C., from about 60° C. to about 70° C., from about 70° C. to about 90° C., from about 90° C. to about 120° C., from about 120° C. to about 150° C., or from about 150° C. to about 180° C. In other embodiments, the temperature for the alkaline solution treatment may be about 50° C., about 60° C., about 70° C., about 75° C., about 80° C., about 90° C., about 120° C., about 150° C., about 180° C., or about 200° C.

The alkaline solution treatment may be carried out for a sufficient time to obtain the p-type metal oxide semiconducting layer 301 having a plurality of nanostructures 302, for example, from about 30 seconds to 30 minutes. In some embodiments, the time for the alkaline solution treatment may range from about 1 minute to about 30 minutes, from about 5 minutes to about 30 minutes, from about 10 minutes to about 30 minutes, from about 20 minutes to about 30 minutes, from about 30 seconds to about 20 minutes, from about 30 seconds to about 10 minutes, from about 30 seconds to about 5 minutes, from about 30 seconds to about 1 minute, from about 1 minutes to about 5 minutes, from about 5 minutes to about 10 minutes, or from about 10 minutes to about 20 minutes. In other embodiments, the time for the alkaline solution treatment may be about 30 seconds, about 1 minute, about 5 minutes, about 10 minutes, about 20 minutes, or about 30 minutes.

In some embodiments, after immersing the metal film 307 in the alkaline solution, the oxidized metal film may be heated. The heating may be carried out at a temperature that does not cause a separation between the substrate and the p-type semiconducting layer, which can generally be determined by routine experimentation. The heating may be carried out at a temperature of, by way of non-limiting example, from about 360° C. to about 2000° C. In some embodiments, the temperature for the heat treatment may range from about 380° C. to about 2000° C., from about 400° C. to about 2000° C., from about 500° C. to about 2000° C., from about 1000° C. to about 2000° C., from about 1500° C. to about 2000° C., from about 360° C. to about 1500° C., from about 360° C. to about 1000° C., from about 360° C. to about 500° C., from about 360° C. to about 400° C., from about 360° C. to about 380° C., from about 380° C. to about 400° C., from about 400° C. to about 500° C., from about 500° C. to about 1000° C., or from about 1000° C. to about 1500° C. In other embodiments, the temperature for the heat treatment may be about 360° C., about 380° C., about 400° C., about 500° C., about 1000° C., about 1500° C., or about 2000° C.

The heat treatment may be carried out, for example, from about 30 seconds to 2 hours. In some embodiments, the time for the heat treatment may range from about 1 minute to about 2 hours, from about 10 minutes to about 2 hours, from about 20 minutes to about 2 hours, from about 30 minutes to about 2 hours, from about 1 hour to about 2 hours, from about 30 seconds to about 1 minute, from about 30 seconds to about 10 minutes, from about 30 seconds to about 20 minutes, from about 30 seconds to about 30 minutes, from about 30 seconds to about 1 hour, from about 1 minute to about 10 minutes, from about 10 minutes to about 20 minutes, from about 20 minutes to about 30 minutes, or from about 30 minutes to about 1 hour. In other embodiments, the time for the heat treatment may be about 30 seconds, about 1 minute, about 3 minutes, about 4 minutes, about 5 minutes, about 10 minutes, about 20 minutes, about 30 minutes, about 1 hour, or about 2 hours.

In accordance with one embodiment by way of non-limiting example, the metal film may be a copper film. The copper film may be prepared by electroplating a substrate, such as glass, plastic, silicon and the like. To form a plurality of nanostructures extending from a p-type semiconducting layer, the copper film is immersed in an alkaline solution. By way of non-limiting example, a mixed solution of sodium chlorite (NaClO₂) and sodium hydroxide (NaOH) may be used for the alkaline solution. When immersed in an alkaline solution, a part of or the entire copper film is oxidized into copper oxide, forming a copper oxide layer that behaves as a p-type semiconducting layer, as well as a plurality of copper oxide nanostructures that extend from the copper oxide layer. The alkaline solution may increase the density of the nanostructures per unit area of the base copper film. In some embodiments, after the oxidation treatment of the copper film with an alkaline solution, an additional heat treatment can be carried out for further development of nanostructure morphology on the p-type semiconducting layer. For example, when heat is applied on the oxidized copper film, additional nanostructures may grow from the copper film or the existing nanostructures may grow longer, in addition to the nanostructures generated by the alkaline solution treatment. In view of the above, the copper film deposited on a substrate may have a thickness of, but is not limited to, from about 2500 Å to about 500 μm, which secures a sufficient source for growing the plurality of copper oxide nanostructures.

In some embodiments, the plurality of nanostructures 302 may also include carbon nanotubes, which may be formed over the p-type semiconducting layer 301 using methods such as, but not limited to, chemical vapor deposition and plasma enhanced chemical deposition.

Referring back to FIG. 3D, a n-type semiconducting layer 303 may be formed on the p-type semiconducting layer 301 and on the plurality of nanostructures 302. In some embodiments, the n-type semiconducting layer 303 may be formed by methods including, but not limited to, spray coating, roller coating, dip coating, spin coating, doctor blade coating, screenprinting, thermal evaporation, e-beam evaporation, vacuum evaporation, high-density plasma assist evaporation, ion plating, sputtering, chemical vapor deposition, metal organic chemical vapor deposition, non-vacuum spray deposition, molecular beam epitaxy, and radiofrequency (RF) magnetron sputtering. The method of forming the n-type semiconducting layer on the p-type semiconducting layer and the plurality of nanostructures may be determined according to the n-type semiconducting material that is being used. For example, titanium dioxide can be coated on a p-type semiconducting layer having a plurality of nanostructures by spray coating, roller coating, dip coating or doctor blade coating of a titanium dioxide slurry, e-beam evaporation or RF magnetron sputtering of titanium dioxide. If zinc oxide is used as the n-type semiconducting material, metal organic chemical vapor deposition, non-vacuum spray deposition, or molecular beam epitaxy can be used. When a transparent conductive film is used as the n-type semiconducting material, sputtering, e-beam evaporation, or high-density plasma assist evaporation may be used, where a high vacuum condition may be needed.

In some embodiments, a method for making a semiconducting device may include providing a substrate, forming a plurality of nanostructures extending from a p-type semiconducting layer on a substrate, forming a n-type semiconducting layer separately, and then attaching the p-type semiconducting layer having the plurality of nanostructures to the n-type semiconducting layer by applying heat and pressure. In some embodiments, the p-type semiconducting layer having the plurality of nanostructures and the n-type semiconducting layer may be pressed together using a heated roll press or another device capable of applying pressure and heat. The heating temperature and the amount of pressure may be determined by routine experimentation and controlled within a range that does not seriously affect or damage the morphology of nanostructures extending from the p-type semiconducting layer for its various uses.

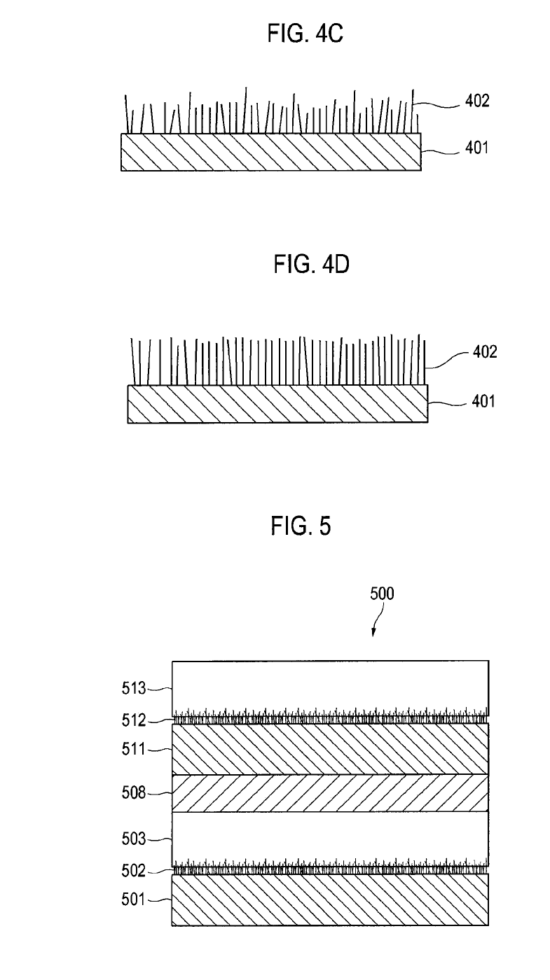

FIGS. 4A-D are schematic diagrams of an illustratives embodiment of a p-type semiconducting layer with a plurality of copper oxide nanostructures extending therefrom. As illustrated in FIG. 4A, a plurality of grassplot-like nanostructures 402 is grown when a copper film is used as a seed layer and is treated with an alkaline solution for 5 min at 75° C. FIG. 4B shows wire-shaped copper oxide nanostructures 402 extending from the oxidized copper film 401 after a heating step at 400° C. for 3 min. FIGS. 4C and 4D show the wire-shaped copper oxide nanostructures 402 extending from the oxidized copper film 401 after an additional heating step at 500° C. for 4 min and 20 min, respectively.

Compared to the nanostructures 402 shown in FIG. 4A, the nanostructures 402 formed on the surface of the oxidized copper film 401 after the additional heat treatment, as illustrated in FIGS. 4B-D, are denser and longer. The copper oxide nanostructures 402 are distributed uniformly on the copper oxide layer 401, as shown in FIGS. 4A-D. Typically, the copper oxide nanostructures 402 include mainly cupric oxide (CuO) but may also include cuprous oxide (Cu₂O).

The heating temperature may affect the morphologies of the copper oxide nanostructures 402. As the heating temperature goes up, the average growth rate of the nanostructures increases, resulting in an increased length and diameter of the nanostructures. For example, when the heating temperature is 400° C., the copper oxide nanostructures 402 grow with an average growth rate of about 0.3 μm/min with a maximum length of about 4 μm and an average diameter of about 20 nm, as illustrated in FIG. 4B. When the heating temperature is 500° C., the copper oxide nanostructures 402 grow with an average growth rate of about 1.5 μm/min with a maximum length of about 6 μm and an average diameter of 100 nm, as illustrated in FIGS. 4C-D. Further, FIGS. 4C and 4D show that the length of the copper oxide nanostructures 402 may become uniform, as the heating time increases. Thus, the diameter, length, and the uniformity of the metal oxide nanostructures could be controlled by adjusting the process conditions, such as heating time and temperature.

Referring to FIG. 5, an illustrative embodiment of a semiconducting device 500 having a plurality of semiconducting layers is shown. The semiconducting device 500 may have a laminated structure including a plurality of units, where each unit has (i) a p-type semiconducting layer 501, 511, (ii) a plurality of nanostructures 502, 512 extending from the p-type semiconducting layer, and (iii) a n-type semiconducting layer 503, 513. FIG. 5 depicts an illustrative embodiment, where a second semiconducting layer unit including layers 511, 512, and 513 is applied onto a first semiconducting layer unit including layers 501, 502, and 503. In other embodiments, additional semiconducting layer units may be consecutively applied to form a laminated structure. By laminating a plurality of semiconducting layer units, the efficiency and the stability of the device can be enhanced.

In some embodiments, the semiconducting layer units in the semiconducting device may be adjacent to one another and form p-n heterojunctions between the n-type semiconducting layer (e.g., 503) of one semiconducting layer unit and the p-type semiconducting layer (e.g., 511) of another adjacent semiconducting layer unit.

In other embodiments, the semiconducting device 500 may be a photovoltaic cell and further include one or more layers, such as window layers (e.g., 508), as illustrated in FIG. 5. The window layer may be configured to serve both as a passivation layer and a reflection layer due to the high electric fields associated with the high energy bandgap. The window layer may be thin and have a wide enough bandgap, so as to let all available light through the heterojunction to the absorbing layer, i.e., the p-type semiconducting layer or the n-type semiconducting layer. Suitable materials for the window layer may include, but are not limited to, AIInP, AlGaAsP, AlGaInAs, AlGaInPAs, GaInP, GaInPAs, AlGaAs, AIInAs, AIInPAs, GaAsSb, AlAsSb, GalnSb, AlGaInSb, AlN, GaN, InN, GaInN, GaInNAs, Si, SiGe, and ZnSSe.

With respect to the semiconducting device shown in FIG. 5, the typical methods for making a semiconducting device 500 are carried out in the same manner as that described above for the embodiment illustrated in FIG. 3, with additional requirements, such as the repetitive lamination of the p-type and the n-type semiconducting layers and optionally other additional layers.

### EXAMPLES

The following example is provided for illustration of some of the illustrative embodiments of the present disclosure but is by no means intended to limit their scope.

### Example 1

### Preparation of a Photovoltaic Cell

A p-type layer having a plurality of nanostructures extending therefrom is prepared by the following process. A copper film of a 3000 Å thickness is prepared by depositing a copper electroplating solution on a glass substrate with a counter electrode of silver. The copper electroplating solution is prepared by mixing 75 g/L of CuSO₄.5H₂O, 180 g/L of H₂SO₄, and 70 mg of HCl.

An alkaline solution is prepared by dissolving 37.5 g sodium chlorite (NaClO₂), 50 g sodium hydroxide (NaOH), and 100 g sodium orthophosphate hydrate (Na₃PO₄.12H₂O) in 100 L of deionized water. The copper film is immersed into the alkaline solution for 5 min at 80° C.

After the oxidation treatment with the alkaline solution, the oxidized copper film is rinsed with deionized water and dried. The oxidized copper film is then heated at 500° C. for 5 min. A hot plate is used as a heating source, and a constant temperature condition is maintained during the heating process. In this way, a number of nanowires grow outward from the oxidized copper film, i.e., the p-type layer.

The n-type layer is formed by RF magnetron sputtering of TiO₂ over the copper oxide film, i.e., p-type layer, and over the plurality of copper oxide nanowires. Doped zinc oxide (ZnO:Al) is deposited on the TiO₂ film by a non-vacuum spray deposition method to form a transparent electrode. In this way, a photovoltaic cell having a p-n heterojunction with a plurality of nanowires is prepared.

### Equivalents

The present disclosure is not to be limited in terms of the particular embodiments described in this application. Many modifications and variations can be made without departing from its spirit and scope, as will be apparent to those skilled in the art. Functionally equivalent methods and apparatuses within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, reagents, compounds, or compositions, which can, of course, vary. It is also to be understood that the terminology used herein is for the purpose of describing particular embodiments only, and is not intended to be limiting.

In view of the present disclosure, those skilled in the art will appreciate that, for this and other processes and methods disclosed herein, the functions performed in the processes and methods may be implemented in differing order. Furthermore, the outlined steps and operations are only provided as examples, and some of the steps and operations may be optional, combined into fewer steps and operations, or expanded into additional steps and operations without detracting from the essence of the disclosed embodiments.

The herein described subject matter sometimes illustrates different components contained within, or connected with, different other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected”, or “operably coupled”, to each other to achieve the desired functionality, and any two components capable of being so associated can also be viewed as being “operably couplable”, to each other to achieve the desired functionality. Specific examples of operably couplable include but are not limited to physically mateable and/or physically interacting components and/or wirelessly interactable and/or wirelessly interacting components and/or logically interacting and/or logically interactable components.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

What is claimed is:

1. A semiconducting device comprising:
a p-type semiconducting layer;
a plurality of nanostructures extending from the p-type semiconducting layer; and
a n-type semiconducting layer,
wherein the n-type semiconducting layer coats the p-type semiconducting layer and the plurality of nanostructures.

2. The semiconducting device of claim 1, wherein the p-type semiconducting layer comprises a metal oxide selected from the group consisting of titanium dioxide and tungsten oxide.

3. The semiconducting device of claim 1, wherein the p-type semiconducting layer comprises a copper oxide selected from the group consisting of cuprous oxide, cupric oxide and a combination thereof.

4. The semiconducting device of claim 1, wherein the n-type semiconducting layer comprises a metal oxide.

5. The semiconducting device of claim 4, wherein the metal oxide is selected from the group consisting of titanium dioxide, tin dioxide and zinc oxide.

6. The semiconducting device of claim 1, wherein the n-type semiconducting layer comprises a transparent conductive film.

7. The semiconducting device of claim 1 further comprising: a substrate on which the p-type semiconducting layer is formed.

8. The semiconducting device of claim 1, wherein the plurality of nanostructures comprises carbon nanotubes.

9. The semiconducting device of claim 1, wherein the n-type semiconducting layer, the p-type semiconducting layer and the plurality of nanostructures form a heterojunction.

10. A photovoltaic cell comprising:
a p-type layer;
a plurality of nanowires protruding from the p-type layer; and
a n-type layer deposited on the p-type layer and the plurality of nanowires forming a heterojunction.

11. The photovoltaic cell of claim 10, wherein the p-type layer comprises a metal oxide selected from the group consisting of titanium dioxide and tungsten oxide.

12. The photovoltaic cell of claim 10, wherein the p-type layer comprises a copper oxide selected from the group consisting of cuprous oxide, cupric oxide and a combination thereof.

13. The photovoltaic cell of claim 10, wherein the n-type layer comprises a metal oxide.

14. The photovoltaic cell of claim 13, wherein the metal oxide is selected from the group consisting of titanium dioxide, tin dioxide and zinc oxide.

15. The photovoltaic cell of claim 10, wherein the n-type layer comprises a transparent conductive film.

16. A method for making a semiconducting device comprising:
forming a plurality of nanostructures extending from a p-type semiconducting layer; and
forming a n-type semiconducting layer on the p-type semiconducting layer and on the plurality of nanostructures.

17. The method of claim 16, wherein the p-type semiconducting layer comprises a metal oxide selected from the group consisting of titanium dioxide and tungsten oxide.

18. The method of claim 16, wherein the p-type semiconducting layer comprises a copper oxide selected from the group consisting of cuprous oxide, cupric oxide and a combination thereof.

19. The method of claim 16, wherein the forming a plurality of nanostructures comprises: immersing a metal film in an alkaline solution.

20. The method of claim 19 further comprising: heating the metal film after the immersing.

21. The method of claim 19, wherein the metal film comprises a metal selected from the group consisting of copper, titanium, and tungsten.

22. The method of claim 19, wherein the metal film has a thickness of from about 1000 Å to 1 mm.

23. The method of claim 20, wherein the heating is carried out at a temperature from about 360° C. to about 2000° C.

24. The method of claim 19, wherein the forming a plurality of nanostructures further comprises: depositing the metal film on a substrate, prior to the immersing.

25. The method of claim 16, wherein the n-type semiconducting layer comprises a metal oxide.

26. The method of claim 25, wherein the metal oxide is selected from the group consisting of titanium dioxide, tin dioxide and zinc oxide.

27. The method of claim 16, wherein the n-type semiconducting layer comprises a transparent conductive film.

28. The method of claim 16, wherein the forming a n-type semiconducting layer is carried out using spray coating, roller coating, dip coating, spin coating, doctor blade coating, screenprinting, thermal evaporation, e-beam evaporation, vacuum evaporation, high-density plasma assist evaporation, ion plating, sputtering, chemical vapor deposition, metal organic chemical vapor deposition, non-vacuum spray deposition, molecular beam epitaxy, or RF magnetron sputtering.

29. A method for making a photovoltaic cell comprising:
forming a plurality of nanowires on a p-type layer; and
coating the plurality of nanowires and the p-type layer with a n-type layer, resulting in a heterojunction.

30. The method of claim 29, wherein the p-type layer comprises a metal oxide selected from the group consisting of titanium dioxide and tungsten oxide.

31. The method of claim 29, wherein the p-type layer comprises a copper oxide selected from the group consisting of cuprous oxide, cupric oxide and a combination thereof.

32. The method of claim 29, wherein the forming a plurality of nanowires comprises: immersing a metal film in an alkaline solution.

33. The method of claim 32 further comprising: heating the metal film after the immersing.

34. The method of claim 32, wherein the metal film comprises a metal selected from the group consisting of copper, titanium, and tungsten.

35. The method of claim 32, wherein the metal film has a thickness of from about 1000 Å to 1 mm.

36. The method of claim 33, wherein the heating is carried out at a temperature from about 360° C. to about 2000° C.

37. The method of claim 32, wherein the forming a plurality of nanowires further comprises: depositing the metal film on a substrate, prior to the immersing.

38. The method of claim 29, wherein the n-type layer comprises a metal oxide.

39. The method of claim 38, wherein the metal oxide is selected from the group consisting of titanium dioxide, tin dioxide and zinc oxide.

40. The method of claim 29, wherein the n-type layer comprises a transparent conductive film.

41. The method of claim 29, wherein the forming a n-type layer is carried out using spray coating, roller coating, dip coating, spin coating, doctor blade coating, screenprinting, thermal evaporation, e-beam evaporation, vacuum evaporation, high-density plasma assist evaporation, ion plating, sputtering, chemical vapor deposition, metal organic chemical vapor deposition, non-vacuum spray deposition, molecular beam epitaxy, or RF magnetron sputtering.
